(19) United States
(12) Patent Application Publication
(10) Pub. No.: US 2024/0321659 A1
(43) Pub. Date: Sep. 26, 2024

(54) DIE-COAT MATERIAL CONFIGURED TO ENHANCE DEVICE RELIABILITY AND DEVICES AND PROCESSES IMPLEMENTING THE SAME

(71) Applicant: WOLFSPEED INC., Durham, NC (US)

(72) Inventors: Afshin DADVAND, Durahm, NC (US); Dev BALARAMAN, Durham, NC (US)

(21) Appl. No.: 18/187,804

(22) Filed: Mar. 22, 2023

(51) Int. Cl. H01L 23/29; C23C 16/26; H01L 23/00

(52) U.S. Cl. CPC H01L 23/29; C23C 16/26; H01L 24/48; H01L 24/32; H01L 24/73; H01L 2224/32245; H01L 2224/48175; H01L 2224/73265

(57) ABSTRACT

A device includes device parts, a diamond-like based material coating arranged on one or more of the device parts. Additionally, the diamond-like based material coating may include at least one of a diamond-like carbon (DLC) material and/or a diamond-like nanocomposite (DLN) material.

### BACKGROUND OF THE DISCLOSURE

Currently, there are a number of materials used as die-coats. However, these die-coat materials provide only limited performance benefits.

Accordingly, what is needed is a die coat material providing improved performance benefits, devices implementing a die coat material providing improved performance benefits, and/or the like as described herein.

### SUMMARY OF THE DISCLOSURE

The foregoing needs are met, to a great extent, by the disclosure, wherein a die-coat material is configured to enhance device reliability, devices implementing a die-coat material configured to enhance device reliability, processes of manufacturing a device having a die-coat material configured to enhance device reliability, processes of manufacturing a die-coat material configured to enhance device reliability, and/or the like are provided.

In one aspect, a device includes device parts. The device in addition includes a diamond-like based material coating arranged on one or more of the device parts. The device moreover includes where the diamond-like based material coating includes at least one of a diamond-like carbon (DLC) material and/or a diamond-like nanocomposite (DLN) material.

In one aspect, a process includes providing device parts. The process in addition includes arranging a diamond-like based material coating on one or more of the device parts. The process moreover includes where the diamond-like based material coating includes at least one of a diamond-like carbon (DLC) material and/or a diamond-like nanocomposite (DLN) material.

In one aspect, a coating includes a diamond-like based material coating. The coating in addition includes where the diamond-like based material coating includes at least one a diamond-like carbon (DLC) material and/or a diamond-like nanocomposite (DLN) material.

In one aspect, a process includes providing a diamond-like based material coating formulated to be arranged on one or more device parts. The process in addition includes where the diamond-like based material coating includes at least one a diamond-like carbon (DLC) material and/or a diamond-like nanocomposite (DLN) material.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a cross-sectional view of a device having device parts with a diamond-like based material coating arranged thereon according to aspects of the disclosure.

FIG. 2 illustrates a cross-sectional view of a device having different device parts with a diamond-like based material coating arranged thereon according to aspects of the disclosure.

FIG. 3 illustrates a cross-sectional view of a device having different device parts with a diamond-like based material coating arranged thereon according to aspects of the disclosure.

FIG. 4 illustrates a cross-sectional view of a diamond-like based material coating arranged on the device parts of the device according to aspects of the disclosure.

FIG. 5 illustrates a top view of the device implementing the device parts according to aspects of the disclosure.

FIG. 6 illustrates a cross-sectional view of the device implementing the device parts according to aspects of the disclosure.

FIG. 7 illustrates a cross-sectional view of the device implementing the device parts according to aspects of the disclosure.

FIG. 8 illustrates a cross-sectional view of a diamond-like based material coating arranged on the device parts of the device according to aspects of the disclosure.

FIG. 9 illustrates a cross-sectional view of a diamond-like based material coating arranged on the device parts of the device according to aspects of the disclosure.

FIG. 10 illustrates a process of manufacturing a device according to aspects of the disclosure.

### DETAILED DESCRIPTION

The disclosure will now be described with reference to the drawing figures, in which like reference numerals refer to like parts throughout. Aspects of the disclosure advantageously provide a die-coat material configured to enhance device reliability, devices implementing a die-coat material configured to enhance device reliability, processes of manufacturing a device having a die-coat material configured to enhance device reliability, processes of manufacturing a die-coat material configured to enhance device reliability, and/or the like.

The disclosure relates to a die-coat material configured to enhance device reliability. The disclosure further relates devices implementing a die-coat material configured to enhance device reliability. The disclosure further relates to processes of manufacturing a device having a die-coat material configured to enhance device reliability. The disclosure further relates to processes of manufacturing a die-coat material configured to enhance device reliability.

Humidity, moisture, and/or the like can typically be a critical factor for reliability of devices, such as discrete devices, discrete power devices, discrete device packages, discrete power device packages, module packages, power module packages, and/or the like. Further, humidity, moisture, and/or the like can typically be a further critical factor for reliability of such devices when a voltage bias, a high voltage bias, a reverse bias, a high reverse bias, and/or the like is applied to the device. For example, under accelerated reliability tests for such devices, such as Temperature Humidity Bias (THB) tests, Biased Highly Accelerated Stress Tests (BHAST), High Humidity, High Temperature Reverse Bias (H3TRB) tests, and/or the like. In this case, such devices typically experience high temperature and high humidity conditions while a voltage bias, a high voltage bias, a reverse bias, a high reverse bias, and/or the like is applied to such devices.

These harsh conditions can accelerate failures in such devices such as metal corrosion, metal migration, ion migration, and/or the like inside the package, interfacial delamination, pop-corn cracking, and/or the like. Moreover, such harsh conditions and/or failures also can activate other degradation mechanisms, failure mechanisms, and/or the like. These costly failures are mainly caused and/or accelerated by a diffusion of the moisture and particularly the humidity inside the package.

Attempts have been made to mitigate an impact on moisture and humidity in devices. For example, polyimides have been used as stress buffer when coated between a die and an epoxy molding compound (EMC) surrounding the die. In some cases, an outside and/or a surface of a module and/or a circuit board is coated with a moisture barrier layer such as parylene or silicon showing some benefit in preventing the moisture. However, these materials cannot withstand high-humidity high-temperature conditions. Moreover, these materials also do not offer desired thermal properties or mechanical properties.

In aspects of the disclosure, a die-coat material may be utilized having a diamond-like based material. For example, a diamond-like carbon (DLC) material, a diamond-like nanocomposite (DLN) material, and/or the like. In this regard, a diamond-like carbon (DLC) is a highly dense material and the diamond-like carbon (DLC) has water, moisture, and humidity barrier properties. In aspects of the disclosure, a diamond-like carbon (DLC) film can be deposited at low temperature and low-cost using cost-effective precursor materials via different deposition methods, such plasma enhanced chemical vapor deposition (PECVD) process.

In further aspects, diamond-like nanocomposite (DLN) coatings may be utilized. In these aspects, the diamond-like nanocomposite (DLN) coatings may be a modified form of the diamond-like carbon (DLC) coatings that may include networks of a-CH and a-SiO. It has been found that the disclosed diamond-like nanocomposite (DLN) coatings may enhance high temperature stability, and significantly lower friction and coating stress.

In further aspects of the disclosure, tuning different material properties of the diamond-like carbon (DLC) coatings and/or the diamond-like nanocomposite (DLN) coatings may be beneficial. For example, tuning different material properties relating to a coefficient of thermal expansion (CTE), conductivity, mechanical properties, and/or the like. In particular aspects, tuning different material properties may include elemental doping, such as with nitrogen, deposition parameters, post-deposition parameters, and/or the like. Additionally, tuning different material properties may include using different precursors to modify final coating characteristics and functionalities.

In aspects of the disclosure, a diamond-like based material coating may include a thin layer of the diamond-like carbon (DLC) and/or a diamond-like nanocomposite (DLN) as a die-coat. In this regard, the disclosed diamond-like based material coating can efficiently prevent or significantly reduce the diffusion of humidity and moisture to different parts of a device, such as a die, wire bonds, and/or the like. Moreover, the disclosed diamond-like based material coating may prevent or significantly mitigate the associated degradations and failures of the device. In this regard, it has been found that the diamond-like nanocomposite (DLN) material coating may offer higher coating adhesion and desirable mechanical and interfacial performance due to its much lower intrinsic compressive stress as well as superior barrier function, such as a lower water vapor transport rate (WVTR), in comparison to the diamond-like carbon (DLC).

According to aspects of the disclosure, a thin layer of DLN or DLC as a die-coat has been found to improve different reliability concerns, such as THB, H3TRB, and/or the like, and also may be beneficial in upgrading package moisture sensitivity level (MSL) ratings. According to aspects of the disclosure, the ability for tuning the CTE of a DLN based die coat and/or a DLC based die coat can also address the CTE mismatch between different components, such as an epoxy molding compound (EMC) and different parts of the die. Accordingly, the diamond-like based material coating may thus offer a viable solution to other failures such as thermal cycling (TC).

In aspects of the disclosure, a diamond-like based material coating, such as a thin layer of DLN and/or DLC as die-coat may also effectively prevent and/or reduce migration and/or diffusion of different ionic impurities, such as sodium (Na), chlorine (Cl), potassium (K), and/or the like presented in the EMC and/or diffused from air toward the die.

Moreover, DLN and DLC are excellent thermal conductors, which can facilitate a rapid conduction of heat, avoiding excessive junction temperature or hot spots in the device, such as on a die and wire bonds thus improving the reliability as well as the electrical performance of the device including a die, a package, a module, and/or the like. In some applications, a bilayer of a second die-coat, such as polyimide and/or the like, as stress-buffer layer as well as the DLN/DLC can be used to further tune the characteristics of the final die-coat layer.

In aspects of the disclosure, the disclosed diamond-like based material coating may enhance a reliability of devices, such as power discrete devices, power module packages, and/or the like under different accelerated reliability tests as well as harsh operational conditions, for example in automotive applications.

In aspects of the disclosure, the disclosed diamond-like based material coating, such as a thin DLN and/or DLC layer as a die coat may offer different unique properties and (multi)functionalities. In aspects of the disclosure, the disclosed diamond-like based material coating may significantly compensate for some of the poor material properties of EMCs specially its high WVTR, low thermal conductivity, different ionic impurities, high CTE, and/or the like.

In aspects of the disclosure, the diamond-like based material coating may be implemented as a die-coat material. In aspects of the disclosure, the diamond-like based material coating may be implemented as conformal coating on discrete packages and/or modules.

In aspects of the disclosure, the diamond-like based material coating may be implemented as a die-coat layer in power discrete packages. In aspects of the disclosure the disclosed diamond-like based material coating may be implemented as a die-coat layer in power modules.

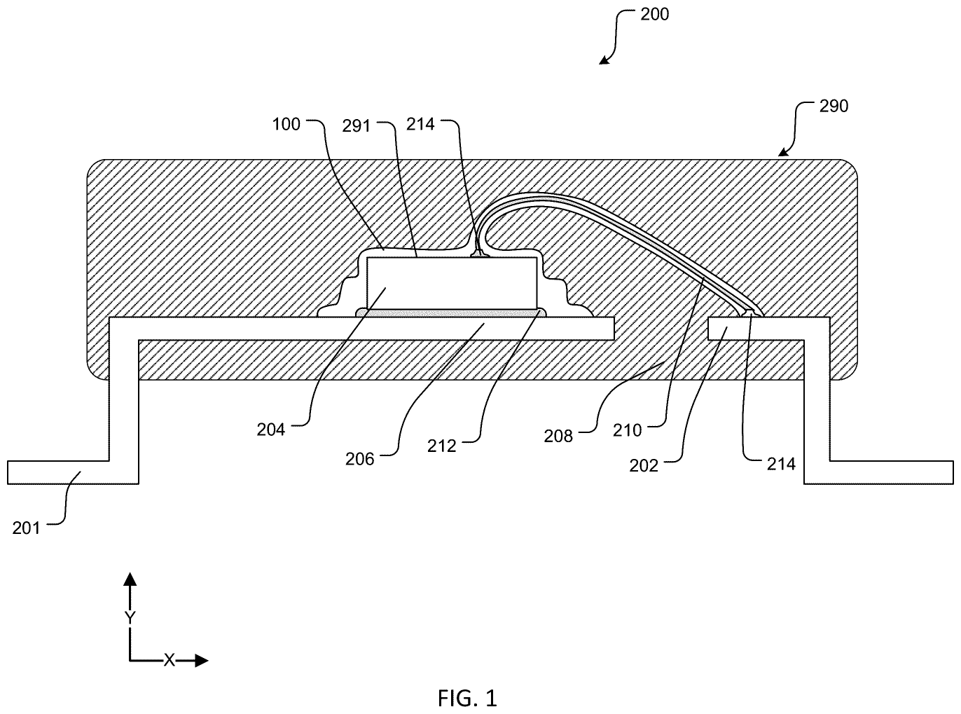

FIG. 1 illustrates a cross-sectional view of a device having device parts with a diamond-like based material coating arranged thereon according to aspects of the disclosure.

In particular, FIG. 1 illustrates a device 200 having device parts 290 with a diamond-like based material coating 100 arranged thereon according to aspects of the disclosure. In aspects, the device 200 may include the device parts 290 and the diamond-like based material coating 100 may be arranged on one or more of the device parts 290. Further, the device 200 may include a molding compound 208 arranged on and/or around one or more of the device parts 290 having the diamond-like based material coating 100 coated thereon; and the device 200 may include the molding compound 208 arranged on one or more of the device parts 290 implemented without the diamond-like based material coating 100 coated thereon. Additionally, one or more the device parts 290 may only be partially covered by the molding compound 208.

In aspects the device 200 and/or the device parts 290 may be one or more of a first lead 201, a second lead 202, at least one device component 204, a mount 206, at least one interconnect 210, a component attach 212, at least one connection 214, and/or the like.

As illustrated in FIG. 1, the diamond-like based material coating 100 may be at least partially arranged on the at least one device component 204, the mount 206, the at least one interconnect 210, the component attach 212, the at least one connection 214, and/or the like.

In other aspects, the diamond-like based material coating 100 may be arranged on fewer components of the device 200. In other aspects, the diamond-like based material coating 100 may be arranged on other components of the device 200. In other aspects, the diamond-like based material coating 100 may be arranged on additional components of the device 200.

In aspects, the diamond-like based material coating 100 may be arranged partially on a single surface of one or more of the device parts 290, the diamond-like based material coating 100 may be arranged partially on multiple surfaces of one or more of the device parts 290, the diamond-like based material coating 100 may be arranged partially on all exposed surfaces of one or more of the device parts 290, the diamond-like based material coating 100 may be arranged partially on all surfaces of one or more of the device parts 290, and/or the like. In this regard, an exposed surface of one or more of the device parts 290 may be a surface that does not include another one of the device parts 290 attached thereto. For example, an upper surface of the at least one device component 204 may be an exposed surface 291 with the exception of a portion of the upper surface where the at least one connection 214 and/or the at least one interconnect 210 are attached and accordingly the exposed surface 291 of the at least one device component 204 may include the diamond-like based material coating 100; and the portion of the upper surface where the at least one connection 214 and/or the at least one interconnect 210 are attached may not include the diamond-like based material coating 100. As an another example, a lower surface of the at least one device component 204 may be attached to the component attach 212 and accordingly may not be an exposed surface and accordingly will not include the diamond-like based material coating 100.

In aspects, the diamond-like based material coating 100 may be arranged entirely on a single surface of one or more of the device parts 290, the diamond-like based material coating 100 may be arranged entirely on multiple surfaces of one or more of the device parts 290, the diamond-like based material coating 100 may be arranged entirely on all exposed surfaces of one or more of the device parts 290, the diamond-like based material coating 100 may be arranged entirely on all surfaces of one or more of the device parts 290, and/or the like.

In aspects, the diamond-like based material coating 100 may be arranged on surfaces of one or more of the device parts 290 that may contact the molding compound 208. In aspects, the diamond-like based material coating 100 may be arranged on surfaces of one or more of the device parts 290 that may directly contact the molding compound 208.

In aspects, the diamond-like based material coating 100 may include a diamond-like based material. For example, the diamond-like based material coating 100 may include a diamond-like carbon (DLC) material, a diamond-like nanocomposite (DLN) material, and/or the like. In this regard, a diamond-like carbon (DLC) is a highly dense material and the diamond-like carbon (DLC) has water, moisture, and humidity barrier properties. In aspects, the DLC material and/or the DLN material may include amounts of sp³ hybridized carbon atoms. In aspects, the DLC material and/or the DLN material may include material with up to two crystalline polytypes including a cubic lattice and a hexagonal lattice. In aspects, the DLC material and/or the DLN material may include amounts of tetrahedral amorphous carbon (ta-C).

In aspects, a film implementation of the diamond-like based material coating 100 may be utilized. In this regard, the film implementation of the diamond-like based material coating 100 may be deposited on the device parts 290 of the device 200 utilizing at low temperature and low-cost using cost-effective precursor materials via different deposition methods, such as vapor deposition process, a plasma enhanced chemical vapor deposition (PECVD) process, and/or the like.

In this regard, low temperature may be less than 100 degrees C., less than 200 degrees C., or less than 300 degrees C.; low temperature may be room temperature (for example, 24 degrees C.) to 100 degrees C., 100-200 degrees C., or 200-300 degrees C. In aspects, application of the diamond-like based material coating 100 at a low temperature, such as a low substrate temperature may prevent and/or reduce interfacial thermal stress, damage, and/or the like.

In aspects, precursor materials for a DLN material implementation of the diamond-like based material coating 100 may include: 3,5,7-Triphenylnonamethylpentasiloxane (C₂₇H₄₂O₄Si₅); a mixture of one or more methane (CH₄), silane (SiH₄), and/or oxygen (O₂); Tetraethylorthosilicate-TEOS (SiC₈H₂₀O₄); Hexamethyldisilane-HMDS (C₆H₁₈Si₂); and/or the like. In aspects, precursor materials for a DLC material implementation of the diamond-like based material coating 100 may include: Mixed gases of one or more of CO₂, C₂H₂, and/or H₂; 2-Methylpropane HC(CH₃)₃; and/or the like.

In aspects, the diamond-like based material coating 100 and can be optionally deposited, arranged, configured, and/or implemented on the device parts 290 of the device 200 without utilizing precursor materials.

In further aspects, diamond-like nanocomposite (DLN) coating materials may be utilized in the diamond-like based material coating 100. In these aspects, the diamond-like nanocomposite (DLN) coating materials of the diamond-like based material coating 100 may be a modified form of the diamond-like carbon (DLC) coating materials. In aspects, the diamond-like nanocomposite (DLN) coating materials of the diamond-like based material coating 100 may include networks of a-CH and a-SiO.

In aspects, the networks of a-CH and a-SiO may include a:SiO and a:CH interpenetrated by Si—C bond within the DLN material. However, the diamond-like nanocomposite (DLN) coating material of the diamond-like based material coating 100 may include other networks and/or other composite materials. Additionally, it has been found that implementations of the diamond-like based material coating 100 utilizing diamond-like nanocomposite (DLN) coating materials may enhance high temperature stability, and significantly lower friction and coating stress for the device parts 290 of the device 200 as well as other components of the device 200. For example, implementations of the diamond-like based material coating 100 utilizing diamond-like nanocomposite (DLN) coating materials may enhance high temperature stability, and significantly lower friction and coating stress between various implementations of the device parts 290 of the device 200.

In further aspects of the disclosure, tuning different material properties of the diamond-like based material coating 100 that include the diamond-like carbon (DLC) coating materials and/or the diamond-like nanocomposite (DLN) coating materials may be beneficial. For example, tuning different material properties of the diamond-like based material coating 100 relating to coefficient of thermal expansion (CTE), conductivity, mechanical properties, and/or the like of the device parts 290 of the device 200. In particular aspects, tuning different material properties of the diamond-like based material coating 100 may include elemental doping, such as with nitrogen, deposition parameters, post-deposition parameters, and/or the like.

In aspects, the diamond-like based material coating 100 may be implemented as a DLC-SiOₓ film that may be deposited in a RF-PECVD system from mixtures of methane (CH₄), silane (SiH₄), Oxygen (O₂), and/or the like onto a surface of the device parts 290 of the device 200 that are placed on a cathode. The RF-power of the RF-PECVD system can be set to control an electrode voltage. The pressure of a chamber of the RF-PECVD system can be maintained lower than <1 Pa. Further, a final thickness of the diamond-like based material coating 100 may be achieved depending on a power setting, a percent volume in the gas feed, a deposition rate, and/or the like.

In particular aspects, the diamond-like based material coating 100 may be implemented as a DLC-SiOx film that may be deposited in a RF-PECVD system implementing an RF frequency of 12 MHz to 14 MHz from mixtures of methane (CH₄), silane (SiH₄, 2-5 percent volume) and Oxygen (O₂, 3-5 percent volume) onto a surface of the device parts 290 of the device 200 that are placed on a cathode. The RF-power of the RF-PECVD system can be set, for example at 100-300 W, to control an electrode voltage of −200 to −800 V. The pressure of a chamber of the RF-PECVD system can be maintained lower than <1 Pa. Further, a final thickness of the diamond-like based material coating 100, such as 1-3 μm may be achieved depending on a power setting, a percent volume in the gas feed, a deposition rate, and/or the like. However, other values of percent volume, frequency, power, and/or the like may be implemented depending on the particular application of the diamond-like based material coating 100.

Additionally, tuning different material properties of the diamond-like based material coating 100 may include using different precursors to modify final coating characteristics and functionalities. The different precursors may include those described herein as well as others. In aspects, the diamond-like based material coating 100 as described herein may be configured, formulated, designed, and/or the like to act as a barrier layer on various implementations of the device parts 290 of the device 200, such as on top of the die. In aspects, final characteristics may include WVTR as well as others. In aspects, a thin-film of the diamond-like based material coating 100 that may include the DLC material and/or the DLN material may be coated and evaluated.

In aspects, the diamond-like based material coating 100 may be implemented as a thin layer die-coat comprising diamond-like carbon (DLC) and/or a diamond-like nanocomposite (DLN). In aspects, the diamond-like based material coating 100 may be implemented as a thin layer on various implementations of the device parts 290 of the device 200 that comprises diamond-like carbon (DLC) and/or a diamond-like nanocomposite (DLN).

In this regard, the diamond-like based material coating 100 as disclosed may be configured and/or formulated to efficiently prevent or significantly reduce the diffusion of humidity and moisture to the device parts 290 of the device 200, such as a die, wire bonds, and/or the like. Moreover, the diamond-like based material coating 100 as disclosed may be configured and/or formulated to prevent or significantly mitigate the associated degradations and failures of the device 200 and/or the device parts 290 of the device 200. In this regard, it has been found that implementations of the diamond-like based material coating 100 that includes the diamond-like nanocomposite (DLN) coating material may offer higher coating adhesion and desirable mechanical and interfacial performance due to its much lower intrinsic compressive stress as well as superior barrier function, such as a lower water vapor transport rate (WVTR), in comparison to the diamond-like carbon (DLC).

According to aspects of the disclosure, implementation of the diamond-like based material coating 100 as a thin layer that includes the diamond-like nanocomposite (DLN) and/or the diamond-like carbon (DLC) as a die-coat has been found to improve different reliability concerns, such as THB, H3TRB, and/or the like, and also may be beneficial in upgrading package moisture sensitivity level (MSL) ratings. According to aspects of the disclosure, the ability for tuning the CTE of the diamond-like based material coating 100 that includes the diamond-like nanocomposite (DLN) and/or the diamond-like carbon (DLC) based die coat can also address the CTE mismatch between the device parts 290 of the device 200, different components, such as the molding compound 208, which may be an EMC, and different parts of the die and/or the device parts 290 of the device 200. Accordingly, the diamond-like based material coating 100 may thus offer a viable solution to other failures such as thermal cycling (TC).

In aspects of the disclosure, the diamond-like based material coating 100, such as a thin layer of DLN and/or DLC as die-coat may also effectively prevent and/or reduce migration and/or diffusion of different ionic impurities, such as sodium (Na), chlorine (Cl), potassium (K), and/or the like presented in the molding compound 208, which may be an epoxy molding compound (EMC), and/or diffused from air toward the die.

In aspects of the disclosure, the diamond-like based material coating 100 reduces corrosion of the device parts 290 of the device 200. In aspects of the disclosure, the diamond-like based material coating 100 reduces a likelihood of corrosion of the device parts 290 of the device 200.

Moreover, DLN and DLC are excellent thermal conductors, which can facilitate a rapid conduction of heat, avoiding excessive junction temperature or hot spots in the device, such as on a die and wire bonds thus improving the reliability as well as the electrical performance of the device including a die, a package, a module, and/or the like.

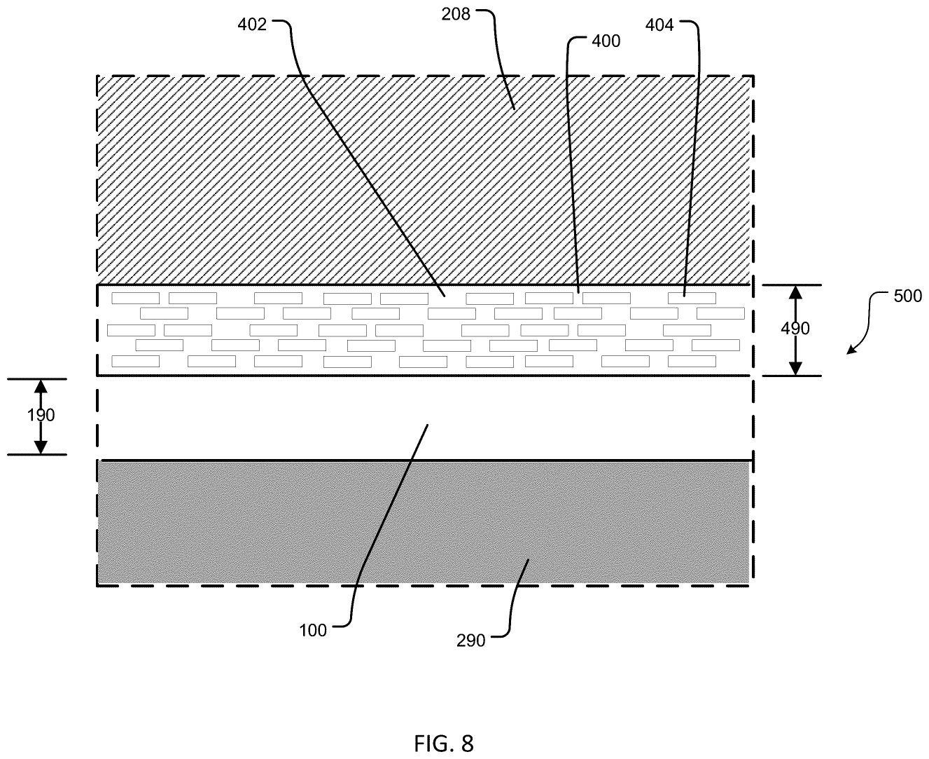

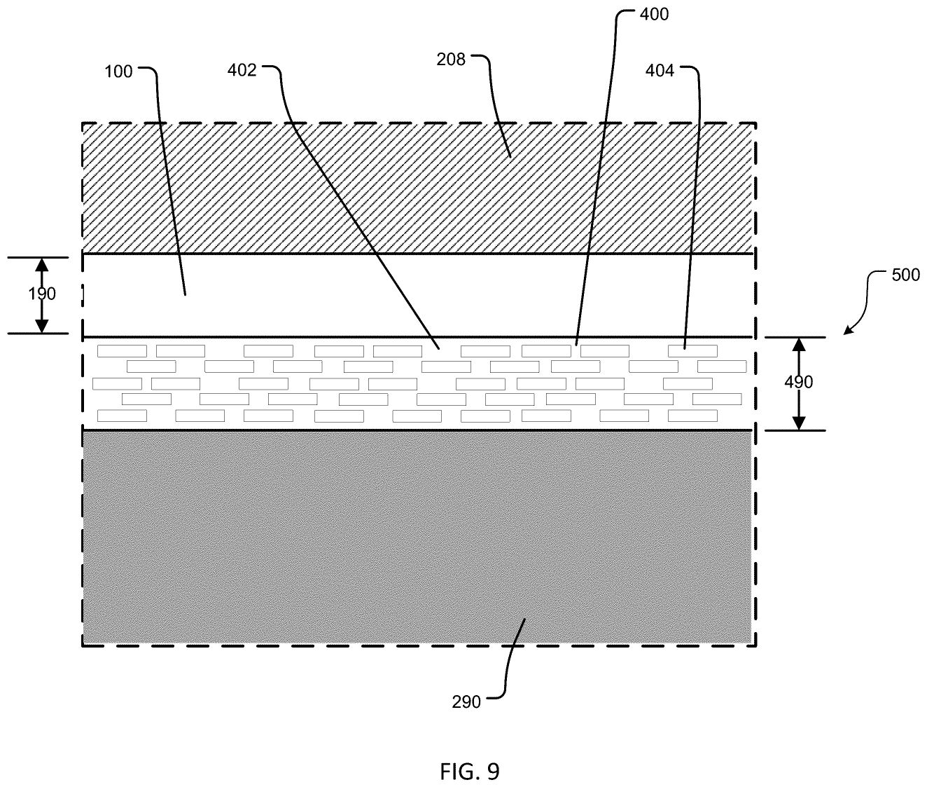

In aspects, the diamond-like based material coating 100 may be implemented as a single layer on at least one of the device parts 290 of the device 200. In aspects, the diamond-like based material coating 100 may be implemented as multiple layers on at least one of the device parts 290 of the device 200. In aspects, the diamond-like based material coating 100 may be implemented as a layer on at least one of the device parts 290 of the device 200 in conjunction with secondary coating material 400 as described with reference to FIG. 8 and FIG. 9 herein.

In aspects, the diamond-like based material coating 100 and the secondary coating material 400 may form a bilayer on at least one of the device parts 290 of the device 200. In aspects, the secondary coating material 400 may comprise polyimide and/or the like, as stress-buffer layer as well as DLN/DLC can be used to further tune the characteristics of the final die-coat layer.

In aspects of the disclosure, the diamond-like based material coating 100 may enhance a reliability of devices, such as power discrete devices, power module packages, and/or the like under different accelerated reliability tests as well as harsh operational conditions, for example in automotive applications.

In aspects of the disclosure, the diamond-like based material coating 100, such as a thin DLN and/or DLC layer as die coat may offer different unique properties and (multi)functionalities. In aspects of the disclosure, the diamond-like based material coating 100 may significantly compensate for some of the poor material properties of the molding compound 208, which may be an EMC, specially its high WVTR, low thermal conductivity, different ionic impurities, high CTE, and/or the like.

In aspects of the disclosure, the diamond-like based material coating 100 may be implemented as a die-coat material. In aspects of the disclosure, the diamond-like based material coating 100 may be implemented as conformal coating on discrete packages and/or modules.

In aspects of the disclosure, the diamond-like based material coating 100 may be implemented as a die-coat layer in power discrete packages. In aspects of the disclosure, the diamond-like based material coating 100 may be implemented as a die-coat layer in power modules.

In aspects, the diamond-like based material coating 100 may be deposited on the device parts 290 of the device 200. In particular aspects, the diamond-like based material coating 100 may be deposited on the device parts 290 by a plasma enhanced chemical vapor deposition (PECVD) process. In aspects, the diamond-like based material coating 100 may be a plasma enhanced chemical vapor deposition coating.

With reference to FIG. 1, the diamond-like based material coating 100 may cover the at least one device component 204, the diamond-like based material coating 100 may partially cover the mount 206, the diamond-like based material coating 100 may cover the component attach 212, the diamond-like based material coating 100 may cover the at least one interconnect 210, the diamond-like based material coating 100 may cover the component attach 212, and/or the diamond-like based material coating 100 may cover the at least one connection 214.

In aspects, the diamond-like based material coating 100 may be arranged on an upper lateral surface of the at least one device component 204, the upper lateral surface being a surface extending along the x-axis as illustrated in FIG. 1. In aspects the diamond-like based material coating 100 may be arranged on at least one vertical surface of the at least one device component 204, the at least one vertical surface being a surface extending along the y-axis as illustrated in FIG. 1. The at least one vertical surface being a surface connected to the upper lateral surface of the at least one device component 204. In aspects, the diamond-like based material coating 100 may be arranged on at least one side surface of the at least one device component 204, the at least one side surface being a surface connected to the upper lateral surface of the at least one device component 204. In aspects, the diamond-like based material coating 100 may completely cover the upper lateral surface of the at least one device component 204, the at least one vertical surface of the at least one device component 204, and the at least one side surface of the at least one device component 204. In aspects, the diamond-like based material coating 100 may completely cover exposed portions of the upper lateral surface of the at least one device component 204, the at least one vertical surface of the at least one device component 204, and the at least one side surface of the at least one device component 204. In aspects, the diamond-like based material coating 100 may completely cover portions of the upper lateral surface of the at least one device component 204, the at least one vertical surface of the at least one device component 204, and the at least one side surface of the at least one device component 204 adjacent the molding compound 208. In aspects, the diamond-like based material coating 100 may partially cover the upper lateral surface of the at least one device component 204, the at least one vertical surface of the at least one device component 204, and the at least one side surface of the at least one device component 204.

In aspects, the diamond-like based material coating 100 may be arranged on an upper lateral surface of the component attach 212, the upper lateral surface being a surface extending along the x-axis as illustrated in FIG. 1. In aspects the diamond-like based material coating 100 may be arranged on at least one vertical surface of the component attach 212, the at least one vertical surface being a surface extending along the y-axis as illustrated in FIG. 1. The at least one vertical surface being a surface connected to the upper lateral surface of the component attach 212. In aspects, the diamond-like based material coating 100 may be arranged on at least one side surface of the component attach 212, the at least one side surface being a surface connected to the upper lateral surface of the component attach 212. In aspects, the diamond-like based material coating 100 may completely cover the upper lateral surface of the component attach 212, the at least one vertical surface of the component attach 212, and the at least one side surface of the component attach 212. In aspects, the diamond-like based material coating 100 may completely cover exposed portions of the upper lateral surface of the component attach 212, the at least one vertical surface of the component attach 212, and the at least one side surface of the component attach 212. In aspects, the diamond-like based material coating 100 may completely cover portions of the upper lateral surface of the component attach 212, the at least one vertical surface of the component attach 212, and the at least one side surface of the component attach 212 adjacent the molding compound 208. In aspects, the diamond-like based material coating 100 may partially cover the upper lateral surface of the component attach 212, the at least one vertical surface of the component attach 212, and the at least one side surface of the component attach 212.

The first lead 201 and/or the second lead 202 may be configured as one or more leadframes, terminals, input pins, output pins and/or the like. The first lead 201 and/or the second lead 202 may comprise a metallic material such as copper, gold, nickel, palladium, silver, and the like, and combinations thereof. A construction of the first lead 201 and/or the second lead 202 may be the same or may be different. The first lead 201 and/or the second lead 202 may comprise any shape, location, arrangement, and/or the like. The arrangements as illustrated in the Figures, are merely exemplary.

The at least one device component 204 may be one or more active devices, passive devices, dies, chips, transistors, and/or the like. In aspects, the at least one device component 204 may be implemented as one or more of the power semiconductor devices, a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a power MOSFET, a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a diode, a power Schottky diode, a gate-controlled thyristor, a Metal Insulator Semiconductor Field Effect Transistor (MISFET), and/or the like. The at least one device component 204 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems.

A power semiconductor device may refer to devices that include one or more power semiconductor die that are designed to carry large currents and/or that are capable of blocking high voltages. Herein, a power semiconductor die refers to a semiconductor die that during normal operation can pass at least 1 Amp of current and/or block at least 100 volts during reverse blocking operation. Power semiconductor die may be fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and/or the like. Power semiconductor die are often packaged to provide a packaged power semiconductor device.

A power MOSFET may be used power semiconductor die. A power MOSFET may be a three terminal device that has gate, drain and source terminals and a semiconductor layer structure that is often referred to as a semiconductor body. A source region and a drain region that are separated by a channel region are formed in the semiconductor body, and a gate electrode (which may act as the gate terminal or be electrically connected to the gate terminal) is disposed adjacent the channel region. The MOSFET may be turned on (to conduct current through the channel region between the source region and drain regions) by applying a bias voltage to the gate electrode, and may be turned off (to block current flow through the channel region) by removing the bias voltage (or reducing the bias voltage below a threshold level).

Aspects of the disclosure may implement the device 200 as a discrete packaged power semiconductor device or multichip power packaged power semiconductor devices. A discrete power packaged power semiconductor device may include a single power semiconductor die, such as a packaged MOSFET, Schottky diode, IGBT and/or the like. The multichip power packaged power semiconductor devices refer to power semiconductor modules that include two or more power semiconductor dies that are provided (and typically interconnected) within a common package.

The mount 206 may be implemented as a metal submount, a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The mount 206 may include an insulating material, a dielectric material, and/or the like.

In aspects, the mount 206 may be implemented as a power substrate that includes a ceramic substrate. In aspects, the power substrate may include a lower metal cladding layer formed on a lower side of the ceramic substrate, and an upper metal cladding layer may be formed on the upper side of the ceramic substrate. As used herein, the term “power substrate” refers to a dielectric substrate that has a metal cladding layer on both sides thereof. In aspects, the power substrate may be an Active Metal Brazed (“AMB”) power substrate, which includes first and second metal braze layers that may be used to bond first and second metal cladding layers, respectively, to the ceramic substrate. In aspects, the power substrate may be a Substrate (or, more typically, a Direct Bonded Copper or “DBC” power substrate, as the metal cladding layers may typically be copper layers).

The molding compound 208 may substantially surround the device parts 290 and may be formed of a plastic or a plastic polymer compound, which may be injection molded around the second lead 202, the at least one device component 204, the mount 206, the at least one interconnect 210, the component attach 212, the at least one connection 214, the device parts 290, and/or the like, thereby providing protection from the outside environment. The molding compound 208 may be formed of a plastic, a mold compound, a plastic compound, a polymer, a polymer compound, a plastic polymer compound, an epoxy molding compound, and/or the like. The molding compound 208 may be injection molded, transfer molded, compression molded, and/or the like around the second lead 202, the at least one device component 204, the mount 206, the at least one interconnect 210, the component attach 212, the at least one connection 214, the device parts 290, and/or the like, thereby providing protection for the device 200, from the outside environment.

The at least one interconnect 210 may be implemented as one or more wires, wire bonds, leads, vias, edge platings, circuit traces, tracks, clips, and/or the like. In one aspect, the at least one interconnect 210 may utilize the same type of connection. In one aspect, the at least one interconnect 210 may utilize different types of connections.

In aspects, the component attach 212 may include implementations of adhesive, soldering, sintering, eutectic bonding, ultrasonically welding, and/or the like as described herein. In aspects, the component attach 212 may be configured to transfer heat to and from the at least one device component 204 and the mount 206.

The at least one connection 214 may utilize ball bonding, wedge bonding, compliant bonding, ribbon bonding, metal clip attach, and/or the like. In one aspect, the at least one connection 214 may utilize the same type of connection. In one aspect, the at least one interconnect 210 may utilize different types of connections. In aspects, the at least one connection 214 may include implementations of adhesive, soldering, sintering, eutectic bonding, ultrasonically welding, and/or the like as described herein.

In aspects, the device 200 may be implemented as a packaged power device, a packaged power semiconductor device, a packaged MOSFET device, a package diode device, a power module, a RF package, a RF amplifier package, a RF power amplifier package, a RF power transistor package, a RF power amplifier transistor package, a component such as a General-Purpose Broadband component, a Telecom component, a L-Band component, a S-Band component, a X-Band component, a C-Band component, a Ku-Band component, a Satellite Communications component, a Doherty configuration, and/or the like.

Additionally, aspects of the diamond-like based material coating 100 and/or the device 200 as illustrated in FIG. 1 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 1.

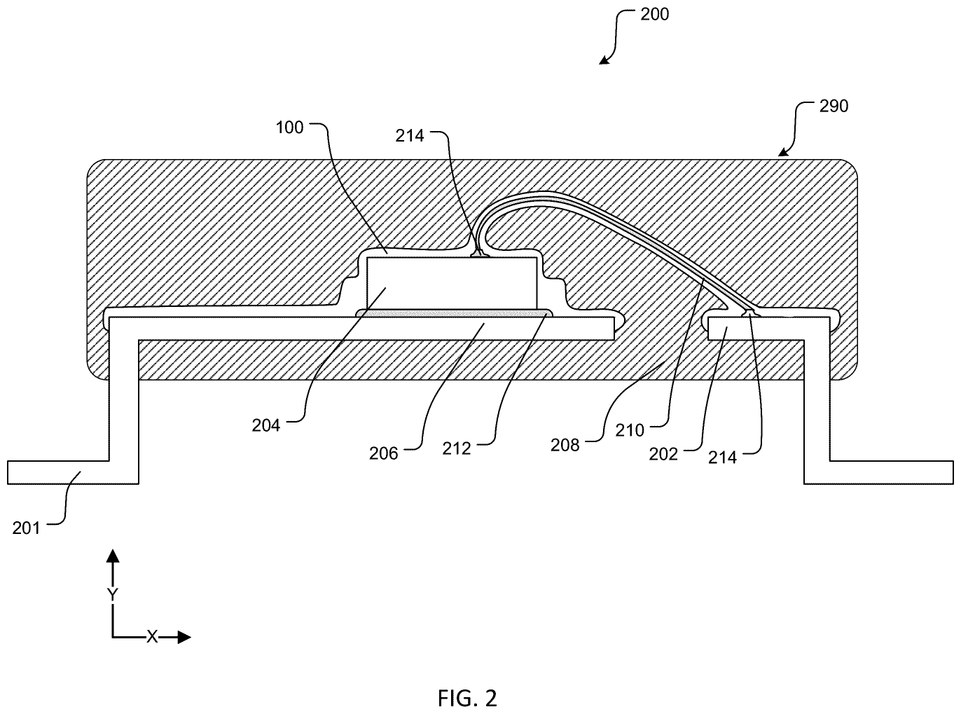

FIG. 2 illustrates a cross-sectional view of a device having different device parts with a diamond-like based material coating arranged thereon according to aspects of the disclosure.

In particular, FIG. 2 illustrates a device 200 having different device parts 290 with a diamond-like based material coating 100 arranged thereon according to aspects of the disclosure. In this regard, aspects of the diamond-like based material coating 100 and/or the device 200 as illustrated in FIG. 2 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 2.

As illustrated in FIG. 2, the diamond-like based material coating 100 may be arranged on one or more of the first lead 201, the second lead 202, the at least one device component 204, the mount 206, the at least one interconnect 210, the component attach 212, the at least one connection 214, and/or the like. In particular aspects, the diamond-like based material coating 100 may be arranged on upper surface of the mount 206 and an upper surface of the second lead 202.

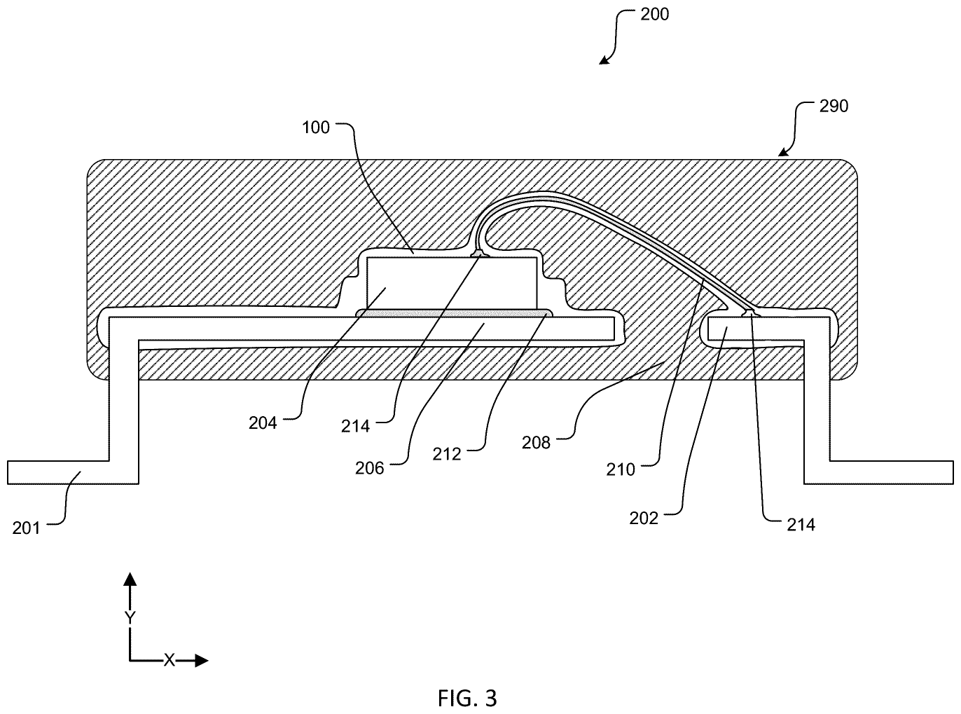

FIG. 3 illustrates a cross-sectional view of a device having different device parts with a diamond-like based material coating arranged thereon according to aspects of the disclosure.

In particular, FIG. 3 illustrates a device 200 having different device parts 290 with a diamond-like based material coating 100 arranged thereon according to aspects of the disclosure. In this regard, aspects of the diamond-like based material coating 100 and/or the device 200 as illustrated in FIG. 3 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 3.

As illustrated in FIG. 3, the diamond-like based material coating 100 may be arranged on one or more of the first lead 201, the second lead 202, the at least one device component 204, the mount 206, the at least one interconnect 210, the component attach 212, the at least one connection 214, and/or the like. In particular aspects, the diamond-like based material coating 100 may be arranged on an upper surface of the mount 206 and an upper surface of the second lead 202. In particular aspects, the diamond-like based material coating 100 may be arranged on a lower surface of the mount 206 and a lower surface of the second lead 202.

In aspects, the diamond-like based material coating 100 may be arranged on an upper lateral surface of the mount 206, the upper lateral surface being a surface extending along the x-axis as illustrated in FIG. 3. In aspects the diamond-like based material coating 100 may be arranged on at least one vertical surface of the mount 206, the at least one vertical surface being a surface extending along the y-axis as illustrated in FIG. 3. The at least one vertical surface being a surface connected to the upper lateral surface of the mount 206. In aspects, the diamond-like based material coating 100 may be arranged on at least one side surface of the mount 206, the at least one side surface being a surface connected to the upper lateral surface of the mount 206. In aspects, the diamond-like based material coating 100 may completely cover the upper lateral surface of the mount 206, the at least one vertical surface of the mount 206, and the at least one side surface of the mount 206. In aspects, the diamond-like based material coating 100 may completely cover exposed portions of the upper lateral surface of the mount 206, the at least one vertical surface of the mount 206, and the at least one side surface of the mount 206. In aspects, the diamond-like based material coating 100 may completely cover portions of the upper lateral surface of the mount 206, the at least one vertical surface of the mount 206, and the at least one side surface of the mount 206 adjacent the molding compound 208. In aspects, the diamond-like based material coating 100 may partially cover the upper lateral surface of the mount 206, the at least one vertical surface of the mount 206, and the at least one side surface of the mount 206.

In aspects, the diamond-like based material coating 100 may be arranged on an upper lateral surface of the second lead 202, the upper lateral surface being a surface extending along the x-axis as illustrated in FIG. 3. In aspects the diamond-like based material coating 100 may be arranged on at least one vertical surface of the second lead 202, the at least one vertical surface being a surface extending along the y-axis as illustrated in FIG. 3. The at least one vertical surface being a surface connected to the upper lateral surface of the second lead 202. In aspects, the diamond-like based material coating 100 may be arranged on at least one side surface of the second lead 202, the at least one side surface being a surface connected to the upper lateral surface of the second lead 202. In aspects, the diamond-like based material coating 100 may completely cover the upper lateral surface of the second lead 202, the at least one vertical surface of the second lead 202, and the at least one side surface of the second lead 202. In aspects, the diamond-like based material coating 100 may completely cover exposed portions of the upper lateral surface of the second lead 202, the at least one vertical surface of the second lead 202, and the at least one side surface of the second lead 202. In aspects, the diamond-like based material coating 100 may completely cover portions of the upper lateral surface of the second lead 202, the at least one vertical surface of the second lead 202, and the at least one side surface of the second lead 202 adjacent the molding compound 208. In aspects, the diamond-like based material coating 100 may partially cover the upper lateral surface of the second lead 202, the at least one vertical surface of the second lead 202, and the at least one side surface of the second lead 202.

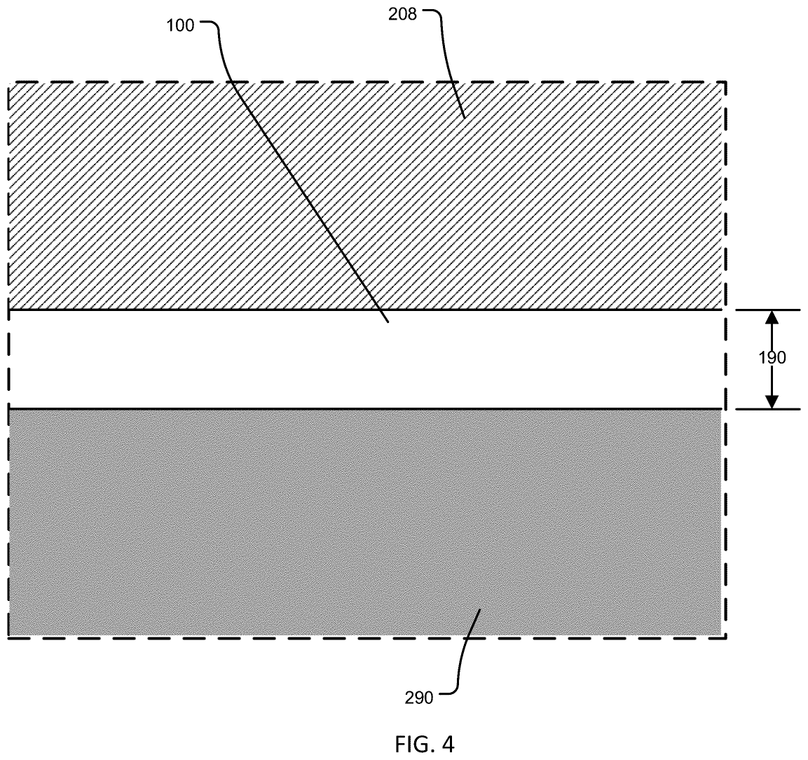

FIG. 4 illustrates a cross-sectional view of a diamond-like based material coating arranged on the device parts of the device according to aspects of the disclosure.

In particular, FIG. 4 illustrates a cross-sectional view of the diamond-like based material coating 100 arranged on one or more of the device parts 290 of the device 200 according to aspects of the disclosure. In this regard, aspects of the diamond-like based material coating 100 and/or the device 200 as illustrated in FIG. 4 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 4.

As illustrated in FIG. 4, the diamond-like based material coating 100 may be arranged on a surface of one or more of the device parts 290 of the device 200. In aspects, the diamond-like based material coating 100 may be arranged directly on a surface of one or more of the device parts 290 of the device 200. In aspects, the diamond-like based material coating 100 may be arranged on a surface of one or more of the device parts 290 of the device 200 with intervening layers of material therebetween.

In aspects, the molding compound 208 may be arranged on a surface of the diamond-like based material coating 100. In aspects, the molding compound 208 may be arranged directly on a surface of the diamond-like based material coating 100. In aspects, the molding compound 208 may be arranged on a surface of the diamond-like based material coating 100 with intervening layers of material therebetween.

In aspects, the diamond-like based material coating 100 may have a thickness 190. In certain implementations of the device parts 290 of the device 200, the thickness 190 of the diamond-like based material coating 100 may be 0.1 to 7 μm, 0.1 to 1 μm, 1 to 2 μm, 2 to 3 μm, 3 to 4 μm, 4 to 5 μm, 5 to 6 μm, or 6 to 7 μm. In certain implementations of the device parts 290 of the device 200, the thickness 190 of the diamond-like based material coating 100 may be less than 7 μm, less than 6 μm, less than 5 μm, less than 4 μm, less than 3 μm, less than 2 μm, or less than 1 μm.

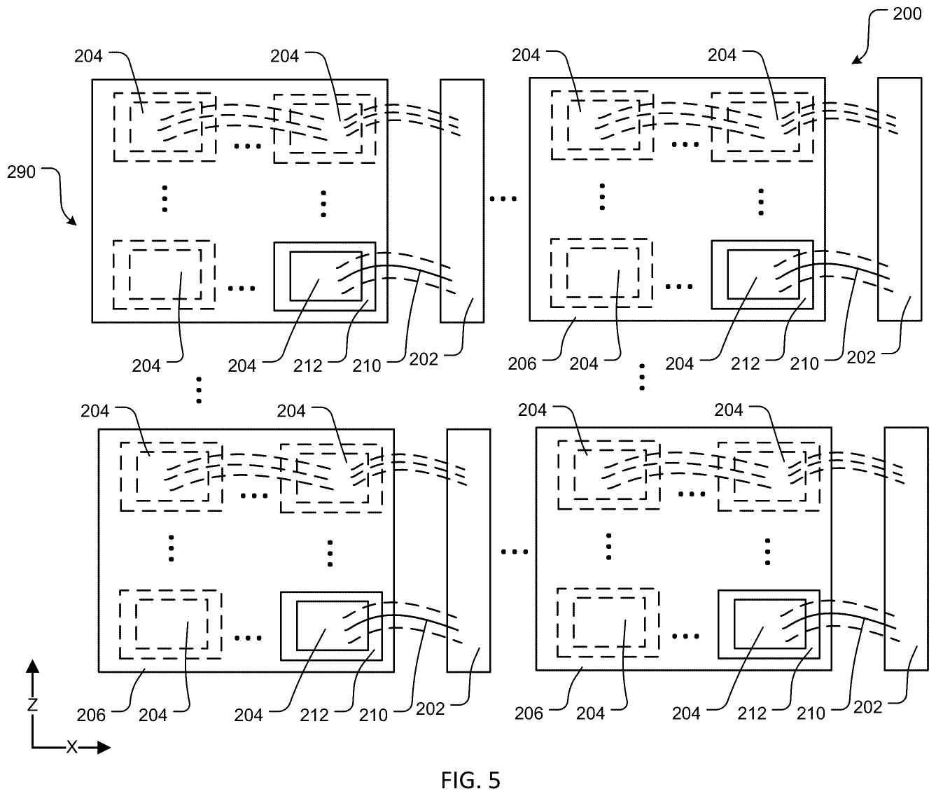

FIG. 5 illustrates a top view of the device implementing the device parts according to aspects of the disclosure.

In particular, FIG. 5 illustrates a top view of the device 200 implementing the device parts 290 according to aspects of the disclosure. In this regard, aspects of the diamond-like based material coating 100 and/or the device 200 as illustrated in FIG. 5 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 5.

FIG. 5 illustrates portions of the device 200 without the molding compound 208 and the diamond-like based material coating 100 for ease of illustration. In this regard, FIG. 5 illustrates that the device 200 may include any number of the at least one device component 204, any number of the at least one interconnect 210, and/or the like. More specifically, there may be any number of the at least one device component 204 extending laterally across the mount 206 along the x-axis; and there may be any number of the at least one device component 204 extending longitudinally across the mount 206 along the z-axis. Additionally, the various implementations of the at least one device component 204 may be different; and/or some of the various implementations of the at least one device component 204 may have the same configuration.

Likewise, there may be any number of the at least one interconnect 210 implemented in the device parts 290 of the device 200. Additionally, the various implementations of the at least one interconnect 210 may be different; and/or some of the various implementations of the at least one interconnect 210 may have the same configuration.

In this regard, aspects of the device 200 implementing the diamond-like based material coating 100 on one or more of the device parts 290 may include any number of the first lead 201, any number of the second lead 202, any number of the mount 206, any number the at least one interconnect 210, and/or the like. Moreover, any one or more of the device parts 290 may include the diamond-like based material coating 100; and any one or more of the device parts 290 of the device 200 may not include the diamond-like based material coating 100.

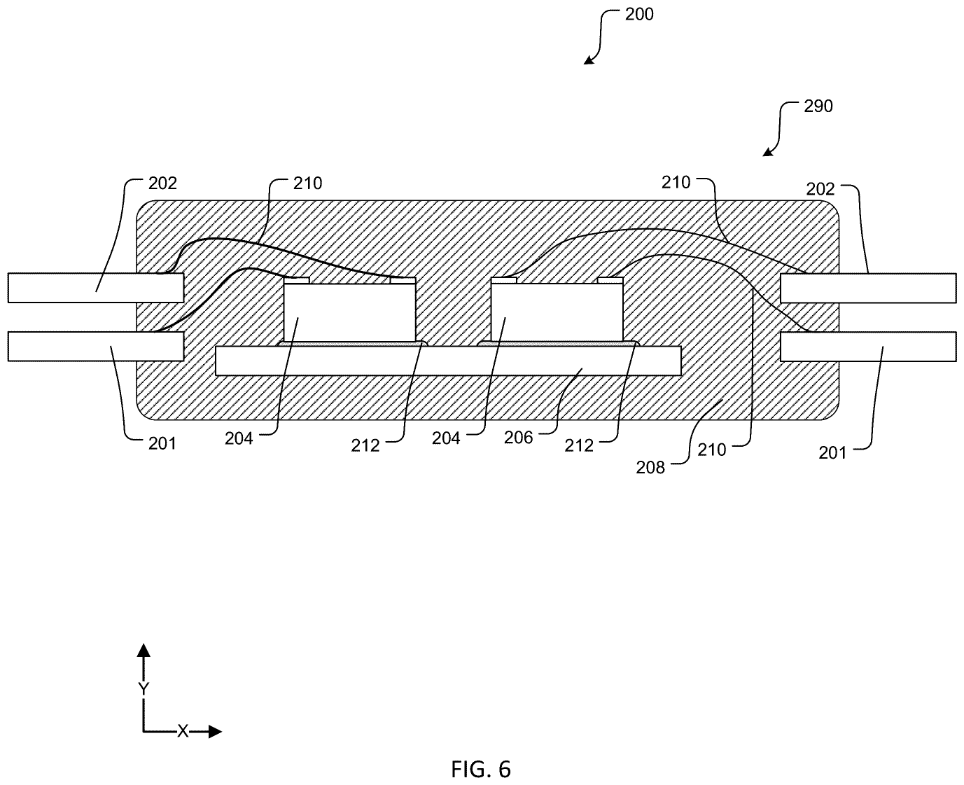

FIG. 6 illustrates a cross-sectional view of the device implementing the device parts according to aspects of the disclosure.

In particular, FIG. 6 illustrates a cross-sectional view of the device 200 implementing the device parts 290 according to aspects of the disclosure. In this regard, aspects of the diamond-like based material coating 100 and/or the device 200 as illustrated in FIG. 6 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 6.

FIG. 6 illustrates portions of the device 200 without the diamond-like based material coating 100 for ease of illustration. In this regard, FIG. 6 illustrates that the device 200 may have a different configuration, number, and/or arrangement of the first lead 201, the second lead 202, the at least one device component 204, the at least one interconnect 210, and/or the like.

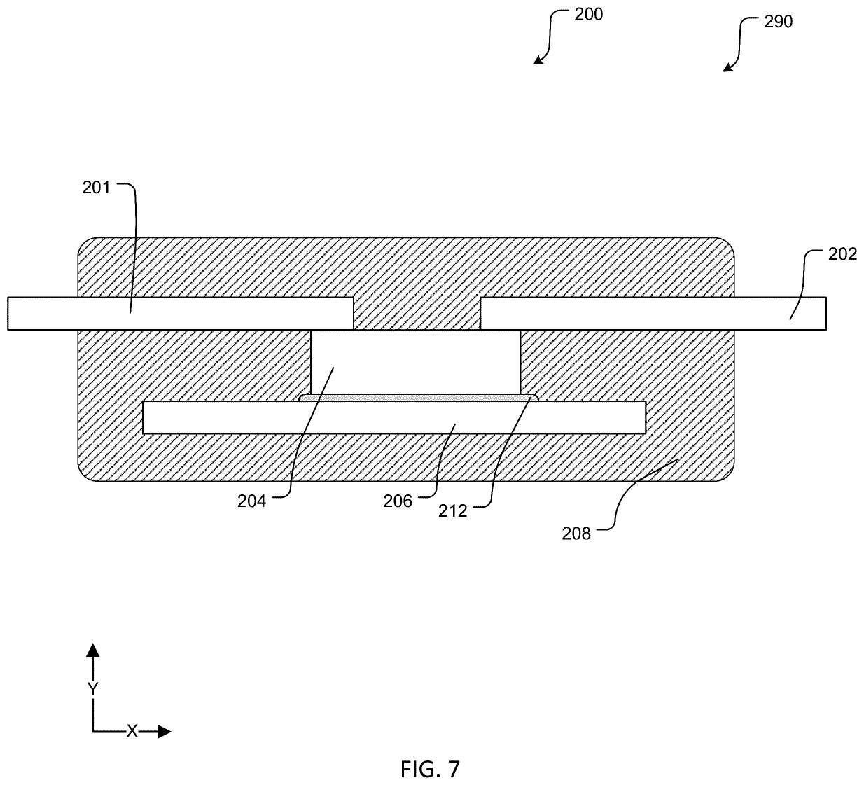

FIG. 7 illustrates a cross-sectional view of the device implementing the device parts according to aspects of the disclosure.

In particular, FIG. 7 illustrates a cross-sectional view of the device 200 implementing the device parts 290 according to aspects of the disclosure. In this regard, aspects of the diamond-like based material coating 100 and/or the device 200 as illustrated in FIG. 7 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 7.

FIG. 7 illustrates portions of the device 200 without the diamond-like based material coating 100 for ease of illustration. In this regard, FIG. 7 illustrates that the device 200 may have a different configuration, number, and/or arrangement of the first lead 201, the second lead 202, the at least one device component 204, and/or the like.

FIG. 8 illustrates a cross-sectional view of a diamond-like based material coating arranged on the device parts of the device according to aspects of the disclosure.

In particular, FIG. 8 illustrates a cross-sectional view of the diamond-like based material coating 100 arranged on one or more of the device parts 290 of the device 200 according to aspects of the disclosure. In this regard, aspects of the diamond-like based material coating 100 and/or the device 200 as illustrated in FIG. 8 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 8.

As illustrated in FIG. 8, the device parts 290 may include a secondary coating material 400. The secondary coating material 400 may be a polyimide material, a ceramic material, a hybrid composite, and/or the like. In this regard, the combination of the diamond-like based material coating 100 and the secondary coating material 400 may form a bilayer 500 on one or more of the device parts 290.

The diamond-like based material coating 100 may be arranged on a surface of one or more of the device parts 290 of the device 200. In aspects, the diamond-like based material coating 100 may be arranged directly on a surface of one or more of the device parts 290 of the device 200. In aspects, the diamond-like based material coating 100 may be arranged on a surface of one or more of the device parts 290 of the device 200 with intervening layers of material therebetween.

The secondary coating material 400 may be arranged on a surface of the diamond-like based material coating 100. In aspects, the secondary coating material 400 may be arranged directly on a surface of the diamond-like based material coating 100. In aspects, the secondary coating material 400 may be arranged on a surface of the diamond-like based material coating 100 with intervening layers of material therebetween.

In aspects, the molding compound 208 may be arranged on a surface of the secondary coating material 400. In aspects, the molding compound 208 may be arranged directly on a surface of the secondary coating material 400. In aspects, the molding compound 208 may be arranged on a surface of the secondary coating material 400 with intervening layers of material therebetween.

In aspects, the secondary coating material 400 may include a hybrid composite of a polymer matrix 402 including and/or incorporating ceramic particles 404. In aspects, the ceramic particles 404 may comprise boron-nitride particles, hexagonal boron-nitride (h-BN) particles, and/or the like. In other aspects, the polymer matrix 402 may include particles of SiNx, Aluminum nitride (AlN), Beryllium oxide (BeO), diamond, and/or the like.

The secondary coating material 400 may be formulated and/or configured to efficiently reduce failures of the device parts 290 of the device 200 associated with interfacial stress during high temperature operation of the device 200. For example, high temperature operation of the device 200 and/or the device parts 290 such as thermal cycling (TC) testing of the device 200 and/or the device parts 290, high temperature reverse bias (HTRB) testing of the device 200 and/or the device parts 290, and/or the like.

In aspects, the polymer matrix 402 may include a polyimide, a silicon, a fluoropolymer, copolymers of polyimide-silicon, and/or the like. In aspects, the ceramic particles 404 may have 5 nm to 5 μm sized h-BN particles. In aspects, the ceramic particles 404 may have 1 nm to 100 nm, 100 nm to 200 nm, 200 nm to 300 nm, 300 nm to 400 nm, 400 nm to 500 nm, 500 nm to 600 nm, 600 nm to 700 nm, 700 nm to 800 nm, 800 nm to 900 nm, 900 nm to 1 μm, 1 μm to 2 μm, 2 μm to 3 μm, 3 μm to 4 μm, 4 μm to 5 μm, or 5 μm to 6 μm sized h-BN particles. In aspects, the ceramic particles 404 may be configured as filler within the secondary coating material 400.

In aspects, the ceramic particles 404 may be utilized in the secondary coating material 400 as hexagonal boron-nitride (h-BN) particles as h-BN is a comparatively soft, low-density material in comparison to numerous other ceramic fillers.

Additionally, in aspects, the ceramic particles 404 may be utilized in the secondary coating material 400 as hexagonal boron-nitride (h-BN) particles as h-BN also possess a very high in-plane and relatively high out-of-plane thermal conductivity up to 600 W/mK and 30 W/mK, respectively. Moreover, the h-BN within the secondary coating material 400 can be formulated and/or configured to dissipate heat in both directions in the device 200 without any or with negligible localized heat that results in minimizing the CTE-mismatch-induced interfacial stress within the within the device parts 290 of the device 200, between the device parts 290 and the molding compound 208, and/or the like, which may be generated during high temperature operation conditions, testing conditions, and/or the like, such as, for example, temperatures exceeding 150 degrees C. In this regard, high temperature operation conditions of the device parts 290 and/or the device 200 are defined as temperatures exceeding 150 degrees C.

In aspects, the ceramic particles 404 of the secondary coating material 400 may include h-BN in forms of h-BN nano-particles, h-BN microparticles, h-BN nanotubes (NT), h-BN pallets, and/or the like. Moreover, the secondary coating material 400 may be implemented in combination with other fillers, such as, Aluminide, silica, and/or the like.

In aspects, the secondary coating material 400 may have a thickness 490. In certain implementations of the device parts 290 of the device 200, the thickness 490 of the secondary coating material 400 may be 2 to 30 μm, 2 to 5 μm, 5 to 10 μm, 10 to 20 μm, or 20 to 30 μm. In certain implementations of the device parts 290 of the device 200, the thickness 490 of the secondary coating material 400 may be less than 10 μm, less than 20 μm, or less than 30 μm. In certain implementations of the device parts 290 of the device 200, the thickness 490 of the secondary coating material 400 may be more than 10 μm, more than 20 μm, more than 30 μm, more than 40 μm, more than 50 μm, or more than 60 μm.

In aspects, the secondary coating material 400 may be deposited on the diamond-like based material coating 100 and/or the device parts 290 of the device 200. In particular aspects, the secondary coating material 400 may be deposited the diamond-like based material coating 100 and/or on the device parts 290 by dispense, inkjet, spray coat, screen print, deposition, dipping, and/or the like.

In particular aspects, the secondary coating material 400 may be a dispensed coating on the diamond-like based material coating 100 and/or the device parts 290. In this aspect, the secondary coating material 400 may be a dispensed coating on the diamond-like based material coating 100 and/or the device parts 290 dispensed from a dispensing device dispensing the secondary coating material 400 onto the diamond-like based material coating 100 and/or one or more the device parts 290.

In particular aspects, the secondary coating material 400 may be an inkjet coating on the diamond-like based material coating 100 and/or the device parts 290. In this aspect, the secondary coating material 400 may be an inkjet coating on the diamond-like based material coating 100 and/or the device parts 290 jetted from an inkjet device jetting the secondary coating material 400 onto the diamond-like based material coating 100 and/or one or more the device parts 290.

In particular aspects, the secondary coating material 400 may be a spray coat coating on the diamond-like based material coating 100 and/or the device parts 290. In this aspect, the secondary coating material 400 may be sprayed on the diamond-like based material coating 100 and/or the device parts 290 sprayed from a spray coating device spraying the secondary coating material 400 onto the diamond-like based material coating 100 and/or one or more the device parts 290.

In particular aspects, the secondary coating material 400 may be a screen printed coating on the diamond-like based material coating 100 and/or the device parts 290. In this aspect, the secondary coating material 400 may be a screen printed coating on the diamond-like based material coating 100 and/or the device parts 290 screen printed from a screen printing device screen printing the secondary coating material 400 onto the diamond-like based material coating 100 and/or one or more the device parts 290.

In aspects, the secondary coating material 400 may be a cured coating that is cured after application of the secondary coating material 400 on the device parts 290. In aspects, after application of the secondary coating material 400 on the device parts 290, the secondary coating material 400 may be degassed at 80-100 degrees C. for 30-60 minutes. Further, the secondary coating material 400 may be cured at 150-250 degrees C. for 30-60 minutes. Other curing and degassing temperatures and times are contemplated as well depending on the application.

Thereafter, the molding compound 208 may be arranged on, arranged around, formed on, formed around, and/or the like the device parts 290 having the secondary coating material 400 coated thereon and the device parts 290 implemented without the secondary coating material 400 coated thereon.

In aspects, preparation of the secondary coating material 400 may optionally include initial processes for preparation of the ceramic particles 404 utilizing hexagonal boron-nitride (h-BN) particles. In aspects, the ceramic particles 404 utilizing the hexagonal boron-nitride (h-BN) particles as described herein may be mixed with the polymer matrix 402 together with any other fillers to form the secondary coating material 400.

In other aspects, the ceramic particles 404 utilizing hexagonal boron-nitride (h-BN) particles may optionally be processed such that the ceramic particles 404 may have a surface functionalization of the hBN particles. Thereafter, the ceramic particles 404 may be processed by grafting the ceramic particles 404 to a polymer, such as a monomer, an oligomer, the polymer matrix 402, and/or the like, which results in a more uniform distribution of the ceramic particles 404 within the secondary coating material 400. Accordingly, in aspects the secondary coating material 400 may include the ceramic particles 404 utilizing the hexagonal boron-nitride (h-BN) particles with surface functionalization. Further, in aspects the secondary coating material 400 may include the ceramic particles 404 grafted to the polymer matrix 402. Additionally, in aspects the secondary coating material 400 may include the hexagonal boron-nitride (h-BN) particles with surface functionalization grafted to the polymer matrix 402.

In aspects, a thin layer of the grafted h-BN hybrid composite implementation of the secondary coating material 400 may be capable of uniformly distributing the interfacial thermomechanical stress, such as posed by the molding compound 208, as well as the heat across the coated area of the device parts 290 and may efficiently prevent or significantly mitigate failures of the device parts 290 such as ratcheting-induced metal delamination, ratcheting-induced metal deformation, passivation layer cracking, SiNx passivation layer cracking, and/or the like during high temperature operational conditions of the device 200, high temperature testing conditions of the device 200, such as HTRB testing, TC testing, stress testing, and/or the like.

FIG. 9 illustrates a cross-sectional view of a diamond-like based material coating arranged on the device parts of the device according to aspects of the disclosure.

In particular, FIG. 9 illustrates a cross-sectional view of the diamond-like based material coating 100 arranged on one or more of the device parts 290 of the device 200 according to aspects of the disclosure. In this regard, aspects of the diamond-like based material coating 100 and/or the device 200 as illustrated in FIG. 9 may optionally be implemented in any other aspects of the diamond-like based material coating 100 and/or the device 200 as described herein. Moreover, aspects of the diamond-like based material coating 100 and/or the device 200 may optionally implement other aspects of the diamond-like based material coating 100 and/or the device 200 as described herein in the aspects of the diamond-like based material coating 100 and/or the device 200 illustrated and described with respect to FIG. 9.

As illustrated in FIG. 9, the secondary coating material 400 may be arranged on a surface of one or more of the device parts 290 of the device 200. In aspects, the secondary coating material 400 may be arranged directly on a surface of one or more of the device parts 290 of the device 200. In aspects, the secondary coating material 400 may be arranged on a surface of one or more of the device parts 290 of the device 200 with intervening layers of material therebetween.

The diamond-like based material coating 100 may be arranged on a surface of the secondary coating material 400. In aspects, the diamond-like based material coating 100 may be arranged directly on a surface of the secondary coating material 400. In aspects, the diamond-like based material coating 100 may be arranged on a surface of the secondary coating material 400 with intervening layers of material therebetween.

In aspects, the molding compound 208 may be arranged on a surface of the diamond-like based material coating 100. In aspects, the molding compound 208 may be arranged directly on a surface of the diamond-like based material coating 100. In aspects, the molding compound 208 may be arranged on a surface of the diamond-like based material coating 100 with intervening layers of material therebetween.

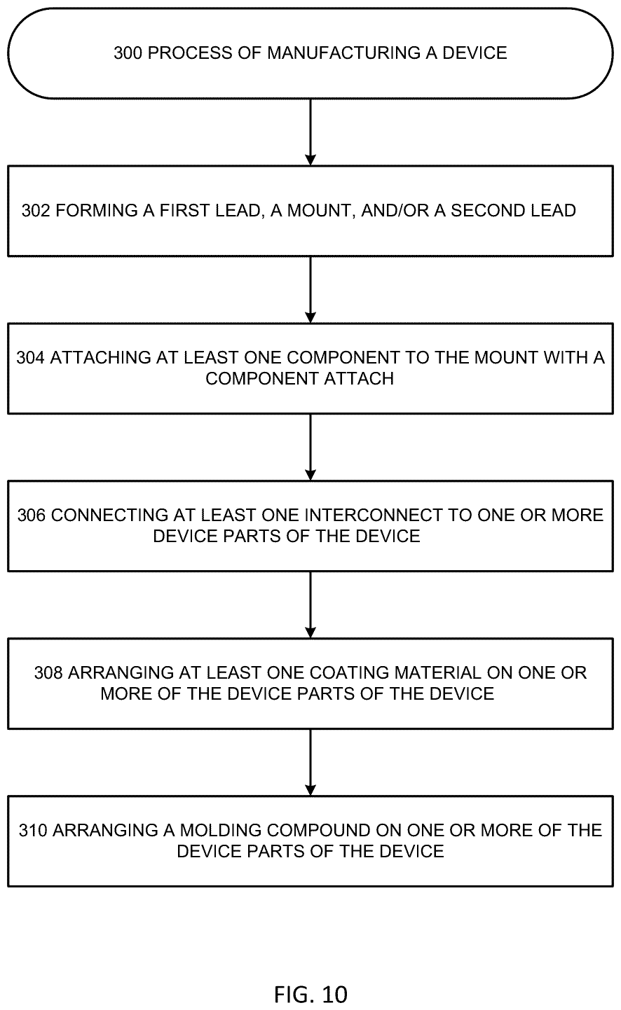

FIG. 10 illustrates a process of manufacturing a device according to aspects of the disclosure.

In particular, FIG. 10 illustrates a process of manufacturing a device 300 according to aspects of the disclosure. In particular, it should be noted that the process of manufacturing a device 300 is merely exemplary and may be modified consistent with the various aspects disclosed herein. Moreover, the process of manufacturing a device 300 of the disclosure may include a process of manufacturing the device 200. It should be noted that the process of manufacturing a device 300 may be performed in a different order consistent with the aspects described above. Moreover, the process of manufacturing a device 300 may be modified to have more or fewer process steps consistent with the various aspects disclosed herein.

The process of manufacturing a device 300 of the disclosure may include forming a first lead, a mount, and/or a second lead 302. In this regard, the forming a first lead, a mount, and/or a second lead 302 may include any one or more materials, structures, arrangements, processes, and/or the like as described herein. Moreover, one or more proceeding or subsequent processes may also be implemented with respect to the forming a first lead, a mount, and/or a second lead 302 consistent with the disclosure.

In particular aspects, the forming a first lead, a mount, and/or a second lead 302 may include forming the first lead 201, the mount 206, the second lead 202, and/or other components of the device 200 as described herein.

The process of manufacturing a device 300 of the disclosure may include attaching at least one component to the mount with a component attach 304. In this regard, the attaching at least one component to the mount with a component attach 304 may include any one or more materials, structures, arrangements, processes, and/or the like as described herein. Moreover, one or more proceeding or subsequent processes may also be implemented with respect to the attaching at least one component to the mount with a component attach 304 consistent with the disclosure.

In particular aspects, the attaching at least one component to the mount with a component attach 304 may include attaching the at least one device component 204 to the mount 206 with the component attach 212 as described herein.

The process of manufacturing a device 300 of the disclosure may include connecting at least one interconnect to one or more device parts of the device 306. In this regard, the connecting at least one interconnect to one or more device parts of the device 306 may include any one or more materials, structures, arrangements, processes, and/or the like as described herein. Moreover, one or more proceeding or subsequent processes may also be implemented with respect to the connecting at least one interconnect to one or more device parts of the device 306 consistent with the disclosure.

In particular aspects, the connecting at least one interconnect to one or more device parts of the device 306 may include connecting the at least one interconnect 210 to one or more of the device parts 290 of the device 200 as described herein.

The process of manufacturing a device 300 of the disclosure may include arranging at least one coating on one or more of the device parts of the device 308. In this regard, the arranging at least one coating on one or more of the device parts of the device 308 may include any one or more materials, structures, arrangements, processes, and/or the like as described herein. Moreover, one or more proceeding or subsequent processes may also be implemented with respect to the arranging at least one coating on one or more of the device parts of the device 308 consistent with the disclosure.

In particular aspects, the arranging at least one coating on one or more of the device parts of the device 308 may include arranging the diamond-like based material coating 100 on one or more of the device parts 290 of the device 200 as described herein. Further, the arranging at least one coating on one or more of the device parts of the device 308 may include arranging the secondary coating material 400 on the diamond-like based material coating 100 as described herein.

Alternatively, the arranging at least one coating on one or more of the device parts of the device 308 may include arranging the secondary coating material 400 on one or more of the device parts 290 of the device 200 as described herein. Further, the arranging at least one coating on one or more of the device parts of the device 308 may include arranging the diamond-like based material coating 100 on the secondary coating material 400 as described herein.

In aspects, the arranging at least one coating on one or more of the device parts of the device 308 may include utilizing a film implementation of the diamond-like based material coating 100. In this regard, the film implementation of the diamond-like based material coating 100 may be deposited on the device parts 290 of the device 200 utilizing at low temperature and low-cost using cost-effective precursor materials via different deposition methods, such as vapor deposition process, a plasma enhanced chemical vapor deposition (PECVD) process, and/or the like. Additionally, the arranging at least one coating on one or more of the device parts of the device 308 may include tuning different material properties of the diamond-like based material coating 100 using different precursors to modify final coating characteristics and functionalities.

In aspects, the arranging at least one coating on one or more of the device parts of the device 308 may include modifying the diamond-like carbon (DLC) coating materials to form diamond-like nanocomposite (DLN) coating materials. In aspects, the arranging at least one coating on one or more of the device parts of the device 308 may include combining the diamond-like nanocomposite (DLN) coating materials of the diamond-like based material coating 100 with networks of a-CH and a-SiO.

In aspects, the arranging at least one coating on one or more of the device parts of the device 308 may include depositing the secondary coating material 400 on the diamond-like based material coating 100 and/or the device parts 290 of the device 200. In particular aspects, the secondary coating material 400 may be deposited on the diamond-like based material coating 100 and/or the device parts 290 by dispense, inkjet, spray coat, screen print, deposition, dipping, and/or the like.

In aspects, the arranging at least one coating on one or more of the device parts of the device 308 may include curing the secondary coating material 400 after application of the secondary coating material 400 on the diamond-like based material coating 100 and/or the device parts 290. In aspects, after application of the secondary coating material 400 on the diamond-like based material coating 100 and/or the device parts 290, the secondary coating material 400 may be degassed at 80-100 degrees C. for 30-60 minutes. Further, the secondary coating material 400 may be cured at 150-250 degrees C. for 30-60 minutes. Other curing and degassing temperatures and times are contemplated as well depending on the application.

In aspects, the arranging at least one coating on one or more of the device parts of the device 308 may include preparing the secondary coating material 400 that may optionally include initial processes for preparation of the ceramic particles 404 utilizing hexagonal boron-nitride (h-BN) particles. In aspects, the ceramic particles 404 utilizing the hexagonal boron-nitride (h-BN) particles as described herein may be mixed with the polymer matrix 402 together with any other fillers to form the secondary coating material 400.

In other aspects, the arranging at least one coating on one or more of the device parts of the device 308 may include processing the ceramic particles 404 utilizing hexagonal boron-nitride (h-BN) particles such that the ceramic particles 404 may have a surface functionalization of the hBN particles. Thereafter, the ceramic particles 404 may be processed by grafting the ceramic particles 404 to a polymer, such as a monomer, an oligomer, the polymer matrix 402, and/or the like, which results in a more uniform distribution of the ceramic particles 404 within the secondary coating material 400. Accordingly, in aspects the secondary coating material 400 may include the ceramic particles 404 utilizing the hexagonal boron-nitride (h-BN) particles with surface functionalization. Further, in aspects the secondary coating material 400 may include the ceramic particles 404 grafted to the polymer matrix 402. Additionally, in aspects the secondary coating material 400 may include the hexagonal boron-nitride (h-BN) particles with surface functionalization grafted to the polymer matrix 402.

The process of manufacturing a device 300 of the disclosure may include arranging a molding compound on one or more of the device parts of the device 310. In this regard, the arranging a molding compound on one or more of the device parts of the device 310 may include any one or more materials, structures, arrangements, processes, and/or the like as described herein. Moreover, one or more proceeding or subsequent processes may also be implemented with respect to the arranging a molding compound on one or more of the device parts of the device 310 consistent with the disclosure.

In particular aspects, the arranging a molding compound on one or more of the device parts of the device 310 may include arranging the molding compound 208 on one or more of the device parts 290 of the device 200 as described herein. In aspects, the arranging a molding compound on one or more of the device parts of the device 310 may include forming the molding compound 208 to substantially surround the device parts 290. The molding compound 208 may be formed of a plastic, a mold compound, a plastic compound, a polymer, a polymer compound, a plastic polymer compound, an epoxy molding compound, and/or the like. The molding compound 208 may be injection molded, transfer molded, compression molded, and/or the like around the second lead 202, the at least one device component 204, the mount 206, the at least one interconnect 210, the component attach 212, the at least one connection 214, the device parts 290, and/or the like, thereby providing protection for the device 200, from the outside environment.

Accordingly, the disclosure has set forth a coat material providing improved performance and increased reliability of devices by reducing an impact of environmental factors including humidity, moisture, and/or the like as described herein.

The following are a number of nonlimiting EXAMPLES of aspects of the disclosure.

One EXAMPLE: a device includes device parts. The device in addition includes a diamond-like based material coating arranged on one or more of the device parts. The device moreover includes where the diamond-like based material coating includes at least one of a diamond-like carbon (DLC) material and/or a diamond-like nanocomposite (DLN) material.

The above-noted EXAMPLE may further include any one or a combination of more than one of the following EXAMPLES:

The device of the above-noted EXAMPLE includes a molding compound arranged on and/or around one or more of the device parts. The device of the above-noted EXAMPLE further where the molding compound is further arranged on one or more of the device parts implemented without the diamond-like based material coating coated thereon. The device of the above-noted EXAMPLE where the diamond-like based material coating is arranged on surfaces of one or more of the device parts that contact the molding compound. The device of the above-noted EXAMPLE where the device parts includes one or more of a first lead, a second lead, at least one device component, a mount, at least one interconnect, a component attach, and/or at least one connection. The device of the above-noted EXAMPLE where the at least one device component includes one or more active devices, passive devices, dies, chips, and/or transistors. The device of the above-noted EXAMPLE where the at least one interconnect includes one or more wires, wire bonds, and/or leads. The device of the above-noted EXAMPLE where the diamond-like based material coating is arranged on all exposed surfaces of one or more of the device parts. The device of the above-noted EXAMPLE where the diamond-like based material coating includes a film deposited, arranged, configured, and/or implemented on one or more of the device parts. The device of the above-noted EXAMPLE where the diamond-like based material coating includes at least one precursor material configured to control coating characteristics and coating functionalities. The device of the above-noted EXAMPLE where the diamond-like based material coating includes a plasma enhanced chemical vapor deposition (PECVD) coating. The device of the above-noted EXAMPLE where the diamond-like based material coating includes the diamond-like nanocomposite (DLN) coating material that includes networks of one or more of a-CH and a-SiO. The device of the above-noted EXAMPLE where the diamond-like based material coating is configured and/or formulated to enhance high temperature stability of one or more of the device parts. The device of the above-noted EXAMPLE where the diamond-like based material coating is configured and/or formulated to lower friction and coating stress between one or more of the device parts and/or between one or more of the device parts and a molding compound. The device of the above-noted EXAMPLE where the diamond-like based material coating includes elemental doping. The device of the above-noted EXAMPLE where the diamond-like based material coating includes nitrogen doping. The device of the above-noted EXAMPLE where the diamond-like based material coating includes a layer on the one or more of the device parts; and where the layer has a thickness of 5 μm or less. The device of the above-noted EXAMPLE where the diamond-like based material coating is configured and/or formulated to reduce a diffusion of humidity and moisture to one or more of the device parts. The device of the above-noted EXAMPLE where the diamond-like based material coating is configured and/or formulated to mitigate degradations and/or failures of one or more of the device parts. The device of the above-noted EXAMPLE where the diamond-like based material coating is configured and/or formulated to reduce migration and/or diffusion of ionic impurities. The device of the above-noted EXAMPLE where the diamond-like based material coating is configured and/or formulated to reduce migration and/or diffusion of ionic impurities presented in a molding compound. The device of the above-noted EXAMPLE where the diamond-like based material coating is configured and/or formulated to facilitate a conduction of heat. The device of the above-noted EXAMPLE where the diamond-like based material coating is implemented as a single layer on one or more of the device parts or as multiple layers on one or more of the device parts. The device of the above-noted EXAMPLE where the diamond-like based material coating is implemented with a second coating layer on one or more of the device parts. The device of the above-noted EXAMPLE where the diamond-like based material coating and the second coating layer form a bilayer on one or more of the device parts. The device of the above-noted EXAMPLE where the second coating layer includes a polyimide material. The device of the above-noted EXAMPLE where the second coating layer includes a composite coating material that includes a polymer matrix including and/or incorporating ceramic particles. The device of the above-noted EXAMPLE where the second coating layer includes a composite coating material that includes a polymer matrix including and/or incorporating hexagonal boron-nitride (h-BN) particles. The device of the above-noted EXAMPLE where the device includes a package, a power device package, and/or a power module.

One EXAMPLE: a process includes providing device parts. The process in addition includes arranging a diamond-like based material coating on one or more of the device parts. The process moreover includes where the diamond-like based material coating includes at least one of a diamond-like carbon (DLC) material and/or a diamond-like nanocomposite (DLN) material.

The above-noted EXAMPLE may further include any one or a combination of more than one of the following EXAMPLES:

The process of the above-noted EXAMPLE includes arranging a molding compound on one or more of the device parts implemented with the diamond-like based material coating coated thereon. The process of the above-noted EXAMPLE includes arranging the molding compound on one or more of the device parts implemented without the diamond-like based material coating coated thereon. The process of the above-noted EXAMPLE where the device parts includes one or more of a first lead, a second lead, at least one device component, a mount, at least one interconnect, a component attach, and/or at least one connection. The process of the above-noted EXAMPLE where the at least one device component includes one or more active devices, passive devices, dies, chips, and/or transistors. The process of the above-noted EXAMPLE where the at least one interconnect includes one or more wires, wire bonds, and/or leads. The process of the above-noted EXAMPLE includes arranging the diamond-like based material coating on all exposed surfaces of one or more of the device parts. The process of the above-noted EXAMPLE includes arranging the diamond-like based material coating on surfaces of one or more of the device parts that contact a molding compound. The process of the above-noted EXAMPLE where the diamond-like based material coating includes a film deposited, arranged, configured, and/or implemented on one or more of the device parts. The process of the above-noted EXAMPLE where the diamond-like based material coating includes at least one precursor material configured to control coating characteristics and coating functionalities. The process of the above-noted EXAMPLE includes applying the diamond-like based material coating utilizing plasma enhanced chemical vapor deposition (PECVD). The process of the above-noted EXAMPLE where the diamond-like based material coating includes the diamond-like nanocomposite (DLN) coating material that includes networks of one or more of a-CH and a-SiO. The process of the above-noted EXAMPLE where the diamond-like based material coating is configured and/or formulated to enhance high temperature stability of one or more of the device parts. The process of the above-noted EXAMPLE where the diamond-like based material coating is configured and/or formulated to lower friction and coating stress between one or more of the device parts and/or between one or more of the device parts and a molding compound. The process of the above-noted EXAMPLE where the diamond-like based material coating includes elemental doping. The process of the above-noted EXAMPLE where the diamond-like based material coating includes nitrogen doping. The process of the above-noted EXAMPLE where the diamond-like based material coating includes a layer on the one or more of the device parts; and where the layer has a thickness of 5 μm or less. The process of the above-noted EXAMPLE where the diamond-like based material coating is configured and/or formulated to reduce a diffusion of humidity and moisture to one or more of the device parts. The process of the above-noted EXAMPLE where the diamond-like based material coating is configured and/or formulated to mitigate degradations and/or failures of one or more of the device parts. The process of the above-noted EXAMPLE where the diamond-like based material coating is configured and/or formulated to reduce migration and/or diffusion of ionic impurities. The process of the above-noted EXAMPLE where the diamond-like based material coating is configured and/or formulated to reduce migration and/or diffusion of ionic impurities presented in a molding compound. The process of the above-noted EXAMPLE where the diamond-like based material coating is configured and/or formulated to facilitate a conduction of heat. The process of the above-noted EXAMPLE includes implementing the diamond-like based material coating as a single layer on one or more of the device parts or as multiple layers on one or more of the device parts. The process of the above-noted EXAMPLE includes implementing a second coating layer on one or more of the device parts. The process of the above-noted EXAMPLE where the diamond-like based material coating and the second coating layer form a bilayer on one or more of the device parts. The process of the above-noted EXAMPLE where the second coating layer includes a polyimide material. The process of the above-noted EXAMPLE where the second coating layer includes a composite coating material that includes a polymer matrix including and/or incorporating ceramic particles. The process of the above-noted EXAMPLE where the second coating layer includes a composite coating material that includes a polymer matrix including and/or incorporating hexagonal boron-nitride (h-BN) particles. The process of the above-noted EXAMPLE includes manufacturing the device as a package, a power device package, and/or a power module.

One EXAMPLE: a coating includes a diamond-like based material coating. The coating in addition includes where the diamond-like based material coating includes at least one of a diamond-like carbon (DLC) material and/or a diamond-like nanocomposite (DLN) material.

The above-noted EXAMPLE may further include any one or a combination of more than one of the following EXAMPLES:

The diamond-like based material coating of the above-noted EXAMPLE where the diamond-like based material coating includes a film deposited, arranged, configured, and/or implemented on one or more of the device parts. The coating of the above-noted EXAMPLE where the diamond-like based material coating includes at least one precursor material configured to control coating characteristics and coating functionalities. The coating of the above-noted EXAMPLE where the diamond-like based material coating includes a plasma enhanced chemical vapor deposition (PECVD) coating. The coating of the above-noted EXAMPLE where the diamond-like based material coating includes the diamond-like nanocomposite (DLN) coating material that includes networks of one or more of a-CH and a-SiO. The coating of the above-noted EXAMPLE where the diamond-like based material coating is configured and/or formulated to enhance high temperature stability of one or more of the device parts. The coating of the above-noted EXAMPLE where the diamond-like based material coating is configured and/or formulated to lower friction and coating stress between one or more device parts and/or between one or more of the device parts a molding compound. The coating of the above-noted EXAMPLE where the diamond-like based material coating includes elemental doping. The coating of the above-noted EXAMPLE where the diamond-like based material coating includes nitrogen doping. The coating of the above-noted EXAMPLE where the diamond-like based material coating includes a layer that includes a thickness of 5 μm or less. The coating of the above-noted EXAMPLE where the diamond-like based material coating is configured and/or formulated to reduce a diffusion of humidity and moisture. The coating of the above-noted EXAMPLE where the diamond-like based material coating is configured and/or formulated to mitigate degradations and/or failures of one or more of the device parts. The coating of the above-noted EXAMPLE where the diamond-like based material coating is configured and/or formulated to reduce migration and/or diffusion of ionic impurities. The coating of the above-noted EXAMPLE where the diamond-like based material coating is configured and/or formulated to reduce migration and/or diffusion of ionic impurities presented in a molding compound. The coating of the above-noted EXAMPLE where the diamond-like based material coating is configured and/or formulated to facilitate a conduction of heat. The coating of the above-noted EXAMPLE where the diamond-like based material coating is implemented as a single layer on one or more of the device parts or as multiple layers on one or more of the device parts. The coating of the above-noted EXAMPLE where the diamond-like based material coating is implemented with a second coating layer on one or more of the device parts. The coating of the above-noted EXAMPLE where the diamond-like based material coating and the second coating layer form a bilayer on one or more of the device parts. The coating of the above-noted EXAMPLE where the second coating layer includes a polyimide material. The coating of the above-noted EXAMPLE where the second coating layer includes a composite coating material that includes a polymer matrix including and/or incorporating hexagonal boron-nitride (h-BN) particles.

One EXAMPLE: a process includes providing a diamond-like based material coating formulated to be arranged on one or more device parts. The process in addition includes where the diamond-like based material coating includes at least one of a diamond-like carbon (DLC) material and/or a diamond-like nanocomposite (DLN) material.

The above-noted EXAMPLE may further include any one or a combination of more than one of the following EXAMPLES:

The process of the above-noted EXAMPLE includes forming the diamond-like based material coating as a film deposited, arranged, configured, and/or implemented on one or more of the device parts. The process of the above-noted EXAMPLE includes adding least one precursor material to the diamond-like based material coating configured to control coating characteristics and coating functionalities. The process of the above-noted EXAMPLE includes applying the diamond-like based material coating utilizing plasma enhanced chemical vapor deposition (PECVD). The process of the above-noted EXAMPLE where the diamond-like based material coating includes the diamond-like nanocomposite (DLN) coating material that includes networks of one or more of a-CH and a-SiO. The process of the above-noted EXAMPLE includes configuring and/or formulating the diamond-like based material coating to enhance high temperature stability of one or more of the device parts. The process of the above-noted EXAMPLE includes formulating and/or configuring the diamond-like based material coating to lower friction and coating stress between one or more of the device parts and/or between one or more of the device parts and a molding compound. The process of the above-noted EXAMPLE includes doping the diamond-like based material coating with elemental doping. The process of the above-noted EXAMPLE includes doping the diamond-like based material coating with nitrogen. The process of the above-noted EXAMPLE includes arranging the diamond-like based material coating in a layer includes a thickness of 5 μm or less. The process of the above-noted EXAMPLE includes formulating and/or configuring the diamond-like based material coating to reduce a diffusion of humidity and moisture to one or more of the device parts. The process of the above-noted EXAMPLE includes formulating the diamond-like based material coating to mitigate degradations and/or failures of one or more of the device parts. The process of the above-noted EXAMPLE includes formulating the diamond-like based material coating to reduce migration and/or diffusion of ionic impurities. The process of the above-noted EXAMPLE includes formulating the diamond-like based material coating to reduce migration and/or diffusion of ionic impurities presented in a molding compound. The process of the above-noted EXAMPLE includes formulating the diamond-like based material coating to facilitate a conduction of heat. The process of the above-noted EXAMPLE includes implementing the diamond-like based material coating with a single layer or multiple layers. The process of the above-noted EXAMPLE includes providing a second coating layer with the diamond-like based material coating. The process of the above-noted EXAMPLE includes forming a bilayer on one or more of the device parts includes the diamond-like based material coating and the second coating layer. The process of the above-noted EXAMPLE where the second coating layer includes a polyimide material. The process of the above-noted EXAMPLE where the second coating layer includes a composite coating material that includes a polymer matrix including and/or incorporating hexagonal boron-nitride (h-BN) particles.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A device comprising:
device parts; and
a diamond-like based material coating arranged on one or more of the device parts, wherein the diamond-like based material coating comprises at least one of a diamond-like carbon (DLC) material and/or a diamond-like nanocomposite (DLN) material.

2. The device according to claim 1 further comprising a molding compound arranged on and/or around one or more of the device parts.

3. The device according to claim 2 further wherein the molding compound is further arranged on one or more of the device parts implemented without the diamond-like based material coating coated thereon.

4. The device according to claim 1 wherein the device parts comprise one or more of a first lead, a second lead, at least one device component, a mount, at least one interconnect, a component attach, and/or at least one connection.

5. The device according to claim 1 wherein the diamond-like based material coating is arranged on all exposed surfaces of one or more of the device parts.

6. The device according to claim 2 wherein the diamond-like based material coating is arranged on surfaces of one or more of the device parts that contact the molding compound.

7. The device according to claim 1 wherein the diamond-like based material coating comprises a film deposited, arranged, configured, and/or implemented on one or more of the device parts.

8. The device according to claim 1 wherein the diamond-like based material coating comprises at least one precursor material configured to control coating characteristics and coating functionalities.

9. The device according to claim 1 wherein the diamond-like based material coating comprises a plasma enhanced chemical vapor deposition (PECVD) coating.

10. The device according to claim 1 wherein the diamond-like based material coating comprises the diamond-like nanocomposite (DLN) coating material that comprises networks of one or more of a-CH and a-SiO.

11. The device according to claim 1 wherein the diamond-like based material coating is configured and/or formulated to enhance high temperature stability of one or more of the device parts.

12. The device according to claim 1 wherein the diamond-like based material coating is configured and/or formulated to lower friction and coating stress between one or more of the device parts and/or between one or more of the device parts and a molding compound.

13. The device according to claim 1 wherein the diamond-like based material coating comprises elemental doping.

14. The device according to claim 1 wherein the diamond-like based material coating comprises nitrogen doping.

15. The device according to claim 1 wherein the diamond-like based material coating comprises a layer on the one or more of the device parts; and wherein the layer has a thickness of 5 μm or less.

16. The device according to claim 1 wherein the diamond-like based material coating is configured and/or formulated to reduce a diffusion of humidity and moisture to one or more of the device parts.

17. The device according to claim 1 wherein the diamond-like based material coating is configured and/or formulated to mitigate degradations and/or failures of one or more of the device parts.

18. The device according to claim 1 wherein the diamond-like based material coating is configured and/or formulated to reduce migration and/or diffusion of ionic impurities.

19. The device according to claim 1 wherein the diamond-like based material coating is configured and/or formulated to reduce migration and/or diffusion of ionic impurities presented in a molding compound.

20. The device according to claim 1 wherein the diamond-like based material coating is configured and/or formulated to facilitate a conduction of heat.

21. The device according to claim 1 wherein the diamond-like based material coating is implemented as a single layer on one or more of the device parts or as multiple layers on one or more of the device parts.

22. The device according to claim 1 wherein the diamond-like based material coating is implemented with a second coating layer on one or more of the device parts.

23. The device according to claim 22 wherein the diamond-like based material coating and the second coating layer form a bilayer on one or more of the device parts.

24. The device according to claim 22 wherein the second coating layer comprises a polyimide material.

25. The device according to claim 22 wherein the second coating layer comprises a composite coating material that comprises a polymer matrix including and/or incorporating ceramic particles.

26. The device according to claim 4 wherein the at least one device component comprises one or more active devices, passive devices, dies, chips, and/or transistors.

27. The device according to claim 4 wherein the at least one interconnect comprises one or more wires, wire bonds, and/or leads.

28. The device according to claim 1 wherein the device comprises a package, a power device package, and/or a power module.

29. A process of manufacturing a device comprising: providing device parts; and
arranging a diamond-like based material coating on one or more of the device parts, wherein the diamond-like based material coating comprises at least one of a diamond-like carbon (DLC) material and/or a diamond-like nanocomposite (DLN) material.

30.-36. (canceled)

37. The process of manufacturing a device according to claim 29 further comprising applying the diamond-like based material coating utilizing plasma enhanced chemical vapor deposition (PECVD).

38.-56. (canceled)
